(19) United States
(12) Patent Application Publication
(10) Pub. No.: US 2013/0206935 A1
(43) Pub. Date: Aug. 15, 2013

(54) Adjustable Electronic Device Holding Apparatus

(71) Applicants: Mohammed Majid, Tampa, FL (US); Crystal Duncan, Tampa, FL (US)

(72) Inventors: Mohammed Majid, Tampa, FL (US); Crystal Duncan, Tampa, FL (US)

(21) Appl. No.: 13/555,631

(22) Filed: Jul. 23, 2012

Related U.S. Application Data
(60) Provisional application No. 61/599,059, filed on Feb. 15, 2012.
(60) Provisional application No. 61/624,061, filed on Apr. 13, 2012.

(51) Int. Cl. H05K 7/18

(52) U.S. Cl. 248/124.1

(57) ABSTRACT

An adjustable holding apparatus includes a length adjustable vertical support member movable between retracted and extended configurations. A base assembly is operatively coupled to a lower end of the vertical support member and configured to support the vertical support member. The base assembly may include a platform having a planar configuration that may slide beneath a sofa cushion, mattress, or be held by a user's foot. In other embodiments, the base assembly may include a tripod. The holding apparatus includes a length adjustable arm member operably coupled to an upper end of the vertical support member upper portion. A holding assembly includes an adjustment portion operably coupled to a distal end of the arm member and includes a holder portion displaced from the adjustment portion. The adjustment portion is may rotate 360 degrees relative to the arm member and the holder portion is configured to selectively secure the electronic device.

### CROSS REFERENCE TO RELATED APPLICATION

This non-provisional patent application claims the benefit of provisional application Ser. No. 61/599,059 filed on Feb. 15, 2012, titled Helping Hand and also claims the benefit of provisional application Ser. No. 61/624,061 filed Apr. 13, 2012, titled Helping Hand.

### BACKGROUND OF THE INVENTION

This invention relates to article holding devices and, more particularly, to an adjustable holding apparatus for holding a normally handheld electronic device hands-free. Specifically, the present invention is a stand that enables an electronic device to be positioned and held in proximity to a user in multiple environments such as in a user's home, in the airport, or anywhere he would otherwise use the electronic device.

When a user desires to use an iPad®, Kindle®, e-reader, or other similar electronic device but is weary of holding it or otherwise desires hands-free use, the user typically tries to prop it up, such as on a bed, couch, bench, chair, or the like. Unfortunately, such usage often leads to dropping the device which may cause it to deactivate or to break. In addition, laying such a device on bedding may cause excessive or even dangerous overheating of the device or bedding. Stated another way, a user has difficulty listening, watching, or using his electronic device while also having to hold it in one or both hands. Holding these devices, especially in awkward positions, such as while lying in bed or on a sofa, can cause substantial arm and hand strain that is undesirable.

Various devices are known in the art for holding articles such as books at selected positions in the air without the use of a user's hands. Although presumably effective for their intended uses, the existing devices do not provide the degree of adjustability needed to hold various sizes of electronic devices, to provide easy rotational orientation adjustments, to be collapsible and portable, and to be selectively positioned on the floor or beneath a sofa cushion, mattress, or the like.

Therefore, it would be desirable to have an adjustable holding apparatus for holding an electronic device that overcomes the limitations of the existing devices and proposals.

### SUMMARY OF THE INVENTION

An adjustable holding apparatus for use in holding an electronic device according to the present invention includes a length adjustable vertical support member having at least a lower portion telescopically coupled to an upper portion and movable between retracted and extended configurations. A base assembly is operatively coupled to a lower end of the lower portion of the vertical support member and configured to support the vertical support member. In some embodiments the base assembly may include a platform having a planar configuration that may slide beneath a couch cushion, mattress, or be held by a user's foot. In other embodiments, the base assembly may be a tripod.

The holding apparatus includes a length adjustable arm member operably coupled to an upper end of the vertical support member upper portion with a pivot coupling and movable between stowed and deployed configurations. A holding assembly includes an adjustment portion operably coupled to a distal end of the arm member and includes a holder portion displaced from the adjustment portion. The adjustment portion is configured to selectively rotate 360 degrees relative to the arm member and the holder portion is configured to selectively secure the electronic device.

Therefore, a general object of this invention is to provide an adjustable apparatus configured to hold an electronic device hands-free, such as for holding an iPad®, Kindle®, e-reader, or other similar handheld electronic device.

Another object of this invention is to provide the adjustable apparatus, as aforesaid, that is adjustable to a user's desired height and lateral distance relative to a base assembly.

Still another object of this invention is to provide the adjustable apparatus, as aforesaid, that is collapsible and portable.

Yet another object of this invention is to provide the adjustable apparatus, as aforesaid, having a base assembly that may be inserted under a sofa cushion, mattress, or be held by a user's foot for use in multiple situations.

A further object of this invention is to provide the adjustable apparatus, as aforesaid, having a holding assembly that may be rotated 360 degrees for adjusting the orientation of an electronic device relative to a user.

A still further object of this invention is to provide the adjustable apparatus, as aforesaid, that is easy to use, store, and transport.

Other objects and advantages of the present invention will become apparent from the following description taken in connection with the accompanying drawings, wherein is set forth by way of illustration and example, embodiments of this invention.

### BRIEF DESCRIPTION OF THE DRAWINGS

FIG. 1a is a perspective view of an adjustable electronic device holding apparatus according to one embodiment of the present invention in a deployed and extended configuration utilizing friction locks that enable fine vertical adjustment variations;

FIG. 1b is another perspective view of the holding apparatus as in FIG. 1a in a fully extended configuration utilizing telescopic structures that enable fixed vertical adjustments;

FIG. 1c is another perspective view of the holding apparatus as in FIG. 1a in a retracted configuration;

FIG. 2 is another perspective view of the holding apparatus as in FIG. 1a;

FIG. 3 is a another perspective view of the holding apparatus in a stowed configuration;

FIG. 4 is an exploded view of the holding apparatus as in FIG. 3;

FIG. 5 is an isolated view on an enlarged scale taken from FIG. 1a;

FIG. 6 is an isolated view on an enlarged scale taken from FIG. 3;

FIG. 7 is a sectional view taken along line 7-7 of FIG. 2;

FIG. 8 is a sectional view taken along line 8-8 of FIG. 2;

FIG. 9 is a perspective view of a holding assembly removed from the holding apparatus of FIG. 1a; and

FIG. 10 is a perspective view of an adjustable electronic device holding apparatus according to another embodiment of the present invention in a deployed configuration.

### DESCRIPTION OF THE PREFERRED EMBODIMENT

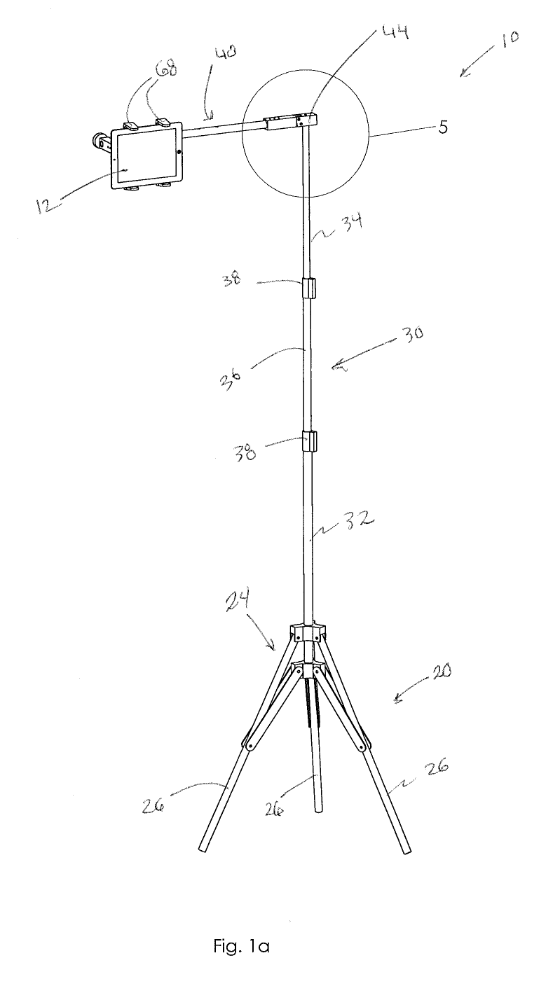

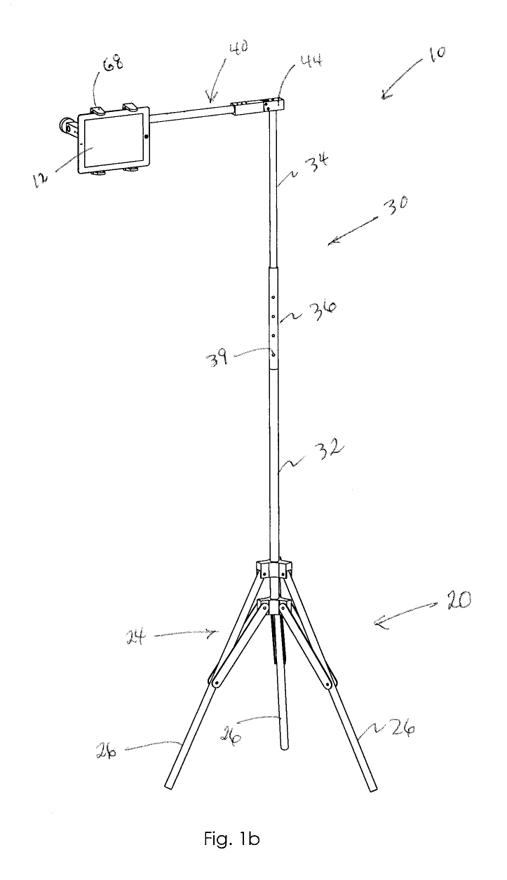

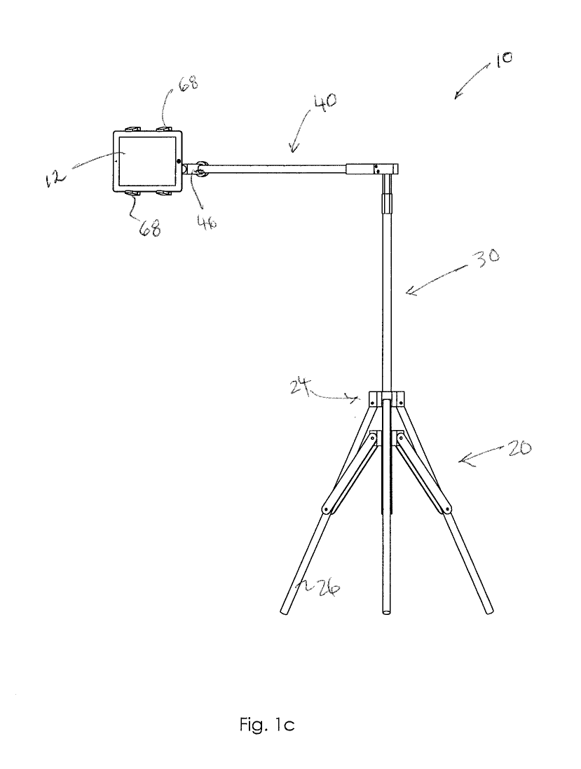

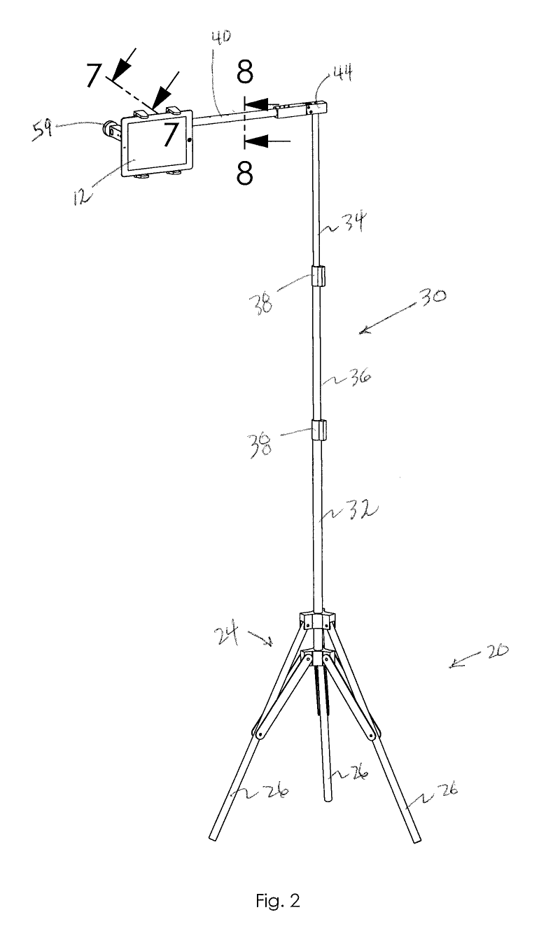

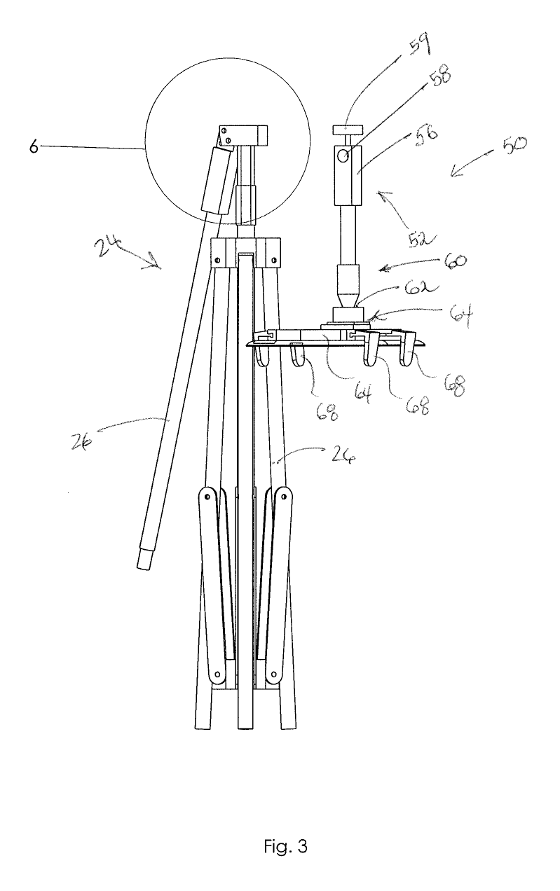

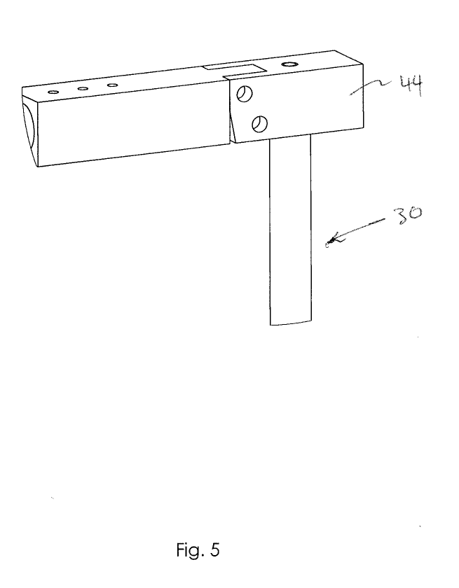

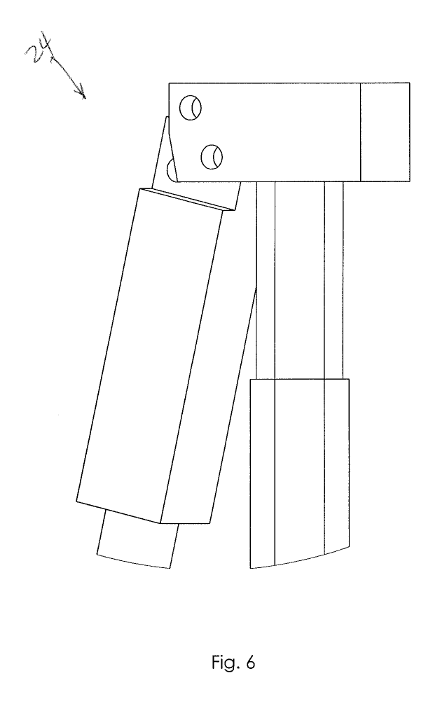

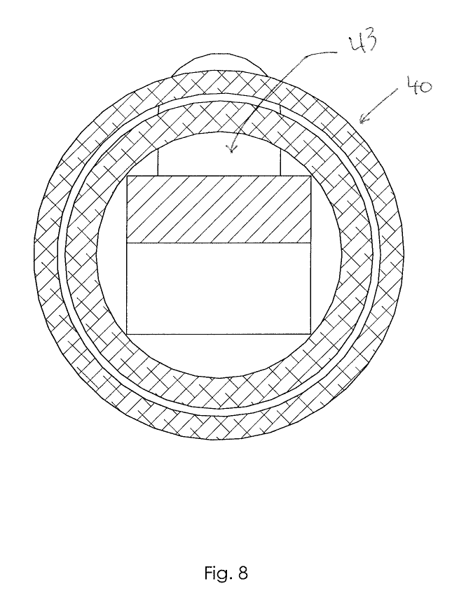

An adjustable electronic device holding apparatus according to the present invention will now be described in detail with reference to FIGS. 1a to 10 of the accompanying drawings. The holding apparatus 10 includes a base assembly 20, a vertical support member 30, an arm member 40, and an electronic device holding assembly 50.

The vertical support member 30 may be a length adjustable rod having at least a lower portion 32 telescopically coupled to an upper portion in a configuration that enables length adjustable movement between a generally retracted configuration and an extended configuration (FIG. 1). In the retracted configuration, the lower portion 32 may be situated substantially inside the upper portion 34 whereas in the extended configuration, the lower portion 32 may be substantially outside the upper portion 34. It is understood, of course, that the larger and smaller of the upper and lower portions may be reversed over what is described herein. It is further understood that the vertical support member 30 may include one or more intermediate portions 36 situated between the upper and lower portions and similarly configured such that the length adjustment of the vertical support member 30 is increased.

The vertical support member portions 32, 34, 36 may be selectively held in user-desired positions in multiple ways. In some embodiments, a friction lock 38 may be situated between immediately adjacent portions of the vertical support member 30 and selectively engaged to either lock the adjacent vertical support member portions at a fixed length adjustment or, conversely, loosened to enable the adjacent vertical support member portions to slide relative to one another, i.e. move to another length adjusted configuration. It is understood that a friction lock length adjustment allows for almost infinite length adjustments.

In another embodiment, respective vertical support member portions may include spaced apart holes and spring-loaded buttons. More particularly, one of the lower 32 or upper 34 vertical support member portions may define a plurality of spaced apart holes 39 while another of the lower 32 or upper 34 vertical support member portions may include a plurality of spaced apart spring-loaded buttons 37. As the vertical support member portions are slidably moved relative to one another, a respective button extends through a respective hole so as to “lock” the portions together. The spring-loaded button 37, of course, may be depressed so as to release the portions to move once again and this method may be repeated until a desired length adjustment is achieved.

The length adjustable arm member 40 is operably coupled to an upper end of the vertical support member 30. The arm member 40, in a construction substantially similar to that of the vertical support member 30 described above, may include multiple arm portions movable relative to one another between a retracted configuration and an extended configuration. It is understood that respective arm member portions may be fixed or movable relative to one another using friction locks or associated holes 42 and buttons 43 as described above. In addition, the arm member 40 may be pivotally coupled to the vertical support member upper end with a pivot coupling 44, such as a hinge, and selectively movable between a stowed configuration generally parallel to the vertical support member 30 and a deployed configuration generally perpendicular to the vertical support member 30.

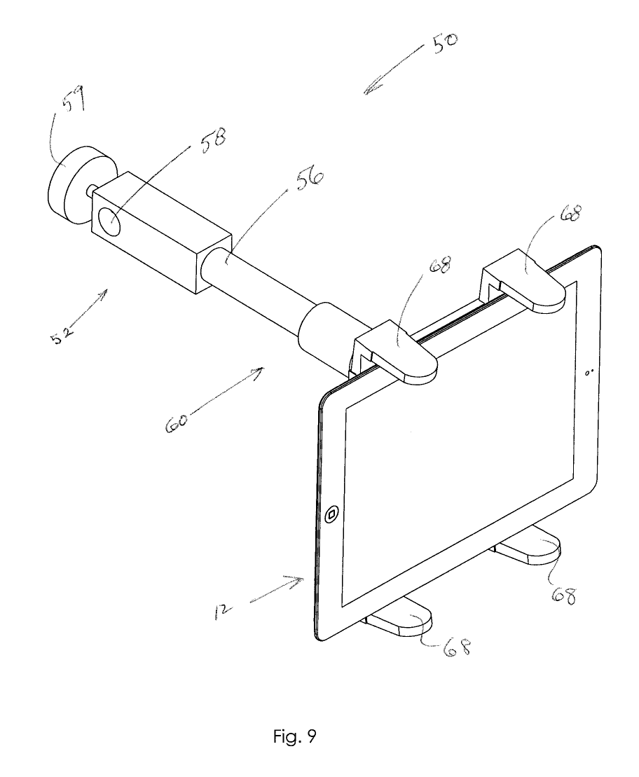

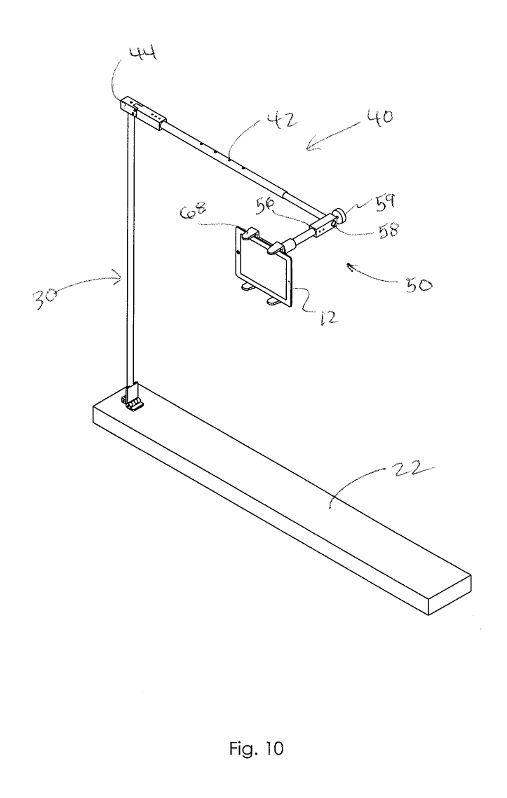

The holding assembly 50 is configured so as to secure an electronic device 12 and to position the electronic device 12 as desired by the user. More particularly, the holding assembly 50 includes an adjustment portion 52 operably coupled to a distal end 46 of the arm member 40 and a holder portion 60 displaced from the adjustment portion 52. As best shown in FIGS. 9 and 10, the adjustment portion 52 may include a shaft 56 defining a bore 58 that is configured to receive the distal end 46 of the arm member 40 such that the shaft 56 is selectively rotatable 360 degrees about an imaginary axis defined by the linear arm member 40. The adjustment portion 52 may also include a locking mechanism 59, such as a friction adjustable knob, in communication with the bore 58 that is configured to selectively allow or prevent the shaft 56 from rotating about the arm member 40. Accordingly, the holding assembly 50 may be adjusted to direct the face an electronic device 12 forward, rearward, upward, downward, or any point therebetween relative to the apparatus 10. It is important to appreciate that this rotational ability is especially useful when holding an iPad having a camera such that the camera may be selectively positioned at virtually any desired angle.

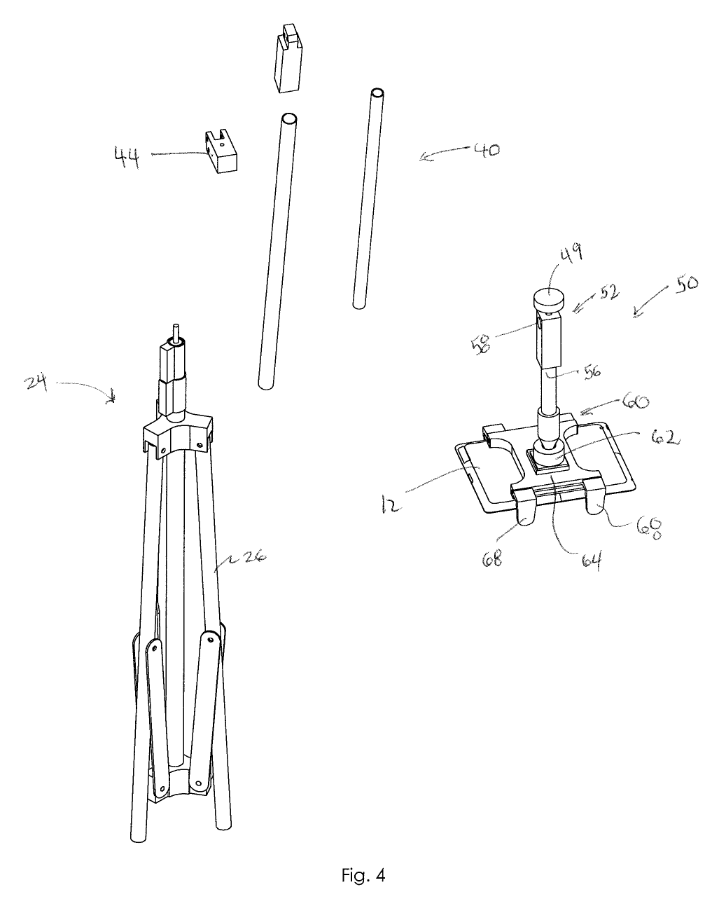

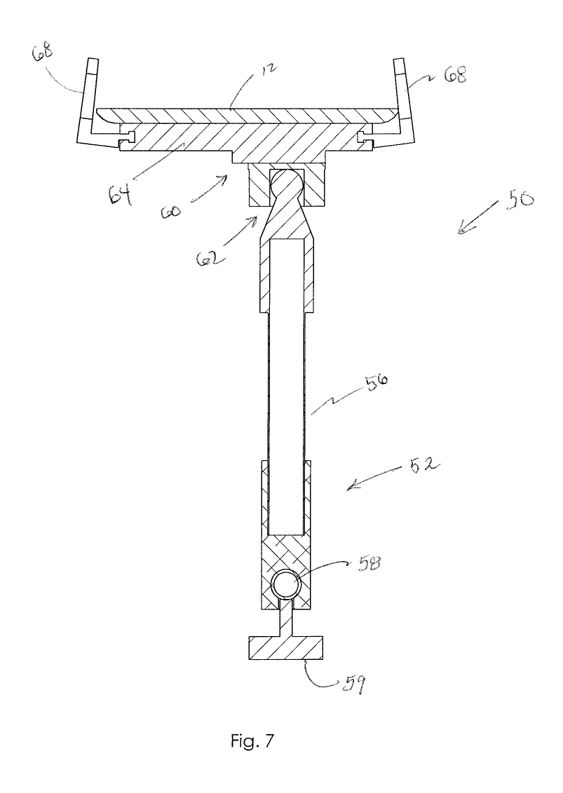

In addition, the holding assembly adjustment portion 52 is operably coupled to the holding assembly holder portion 60 with a rotational coupling 62, such as a ball and socket joint, such that the holder portion 60 may be selectively tilted laterally and vertically relative to the adjustment portion 52. The holder portion 60 includes a framework 64 having peripheral edges 66 (FIG. 4). The adjustment portion shaft 56 is rotatably coupled to a rear of the framework 64 as shown in FIG. 7. Still further, the holder portion 60 includes a plurality of fingers 68 coupled to respective framework peripheral edges 66. It is understood that the fingers 68 may be configured to receive an electronic device 12, such as in a snap-fit or other frictional reception. The fingers 68 may be include a spring-loaded configuration so as to be inwardly biased to receive electronic devices 12 of various dimensions and releasably secure them to the framework 64.

The adjustable holding apparatus 10 includes a base assembly 20 for supporting the structures described above. In one embodiment, the base assembly 20 may be a platform 22 coupled to a lower end of the vertical support member 30 (FIG. 10). The platform 22 may be pivotally coupled to the vertical support member 30 such that the platform 22 is selectively movable between a folded configuration generally parallel and adjacent to the vertical support member 30 and an unfolded configuration generally perpendicular to the vertical support member 30. The unfolded configuration is a use configuration such that the platform 22 supports the apparatus 10 on a floor or ground surface. Preferably, the platform 22 includes a thin thickness such that the platform 22 may be inserted beneath a sofa cushion or a bed mattress and used as will be described below. Further, a user may sit on the platform 22 or press the weight of his foot thereon so as to stabilize the apparatus 10 in home or travel situations.

In another embodiment, the base assembly 20 may include a tripod 24 having a plurality of legs 26 movable between retracted and extended configurations. At the retracted configuration (FIG. 4), the legs 26 are generally parallel to one another so that the base assembly 20 is portable. At the extended configuration (FIG. 1), the legs 26 are spaced apart such that the tripod 24 will support the apparatus 10 above a floor surface.

In use, the adjustable holding apparatus 10 may be used to hold an electronic device 12 for hands-free use as described below. The apparatus 10 may be quickly deployed for use by manually moving the base assembly 20, vertical support member 30, and arm member 40 to their respective extended or use configurations as described above. When the desired length adjustments have been made, the respective members may be locked into place using the friction lock 38, spring-loaded buttons, or friction locking mechanism 59 as previously described. An electronic device 12 may then be snapped into the framework 64 and fingers 68 of the holding assembly holder portion 60 and the holding assembly 50 rotationally positioned. In an embodiment including a platform 22 as the base assembly 20, the platform 22 may be inserted beneath a sofa cushion or mattress and then the user may sit atop the cushion or mattress such that the apparatus 10 may be utilized as previously described.

Accordingly, the adjustable electronic device holding apparatus 10 enables a user to view and utilize an electronic device without having to otherwise hold the device with one or both hands.

It is understood that while certain forms of this invention have been illustrated and described, it is not limited thereto except insofar as such limitations are included in the following claims and allowable functional equivalents thereof.

1. An adjustable holding apparatus for use in holding an electronic device, comprising:
a length adjustable vertical support member having at least a lower portion telescopically coupled to an upper portion and selectively movable between a retracted configuration in which said upper portion is substantially inside said lower portion and an extended configuration in which said upper portion is partially outside said lower portion;
a base assembly operatively coupled to a lower end of said lower portion of said vertical support member and configured to support said vertical support member;
a length adjustable arm member operably coupled to an upper end of said vertical support member upper portion with a pivot coupling, said arm member being selectively movable between a stowed configuration generally parallel to said vertical support member and a deployed configuration generally perpendicular to said vertical support member;
a holding assembly having an adjustment portion operably coupled to a distal end of said arm member and a holder portion displaced from said adjustment portion;
wherein said adjustment portion is configured to selectively rotate said holding assembly 360 degrees relative to said arm member; and
wherein said holder portion is configured to selectively secure the electronic device.

2. The adjustable holding apparatus as in claim 1, wherein said vertical support member lower portion is coupled relative to said vertical support member upper portion with a friction lock.

3. The adjustable holding apparatus as in claim 1, wherein said vertical support member includes an intermediate portion situated intermediate said upper portion and said lower portion and configured to be selectively held in a fixed relationship relative thereto.

4. The adjustable holding apparatus as in claim 1, wherein said adjustment portion of said holding assembly includes:
a shaft defining a bore at a proximal end that is configured to receive said distal end of said arm member and that allows said shaft to selectively rotate about an imaginary longitudinal axis defined by said arm member; and
a locking mechanism in communication with said bore and configured to selectively tighten against said distal end of said arm member to prevent said shaft from rotating about said arm member.

5. The adjustable holding apparatus as in claim 4, wherein said holding assembly adjustment portion is operably coupled to said holding assembly holder portion with a ball and socket joint such that said holder portion is selectively tilted laterally and vertically relative to said adjustment portion.

6. The adjustable holding apparatus as in claim 5, wherein said holder portion includes a framework and a plurality of spring-loaded fingers coupled to said framework, each said finger being configured to move between a normally retracted configuration and an extended configuration, whereby said holder portion is size adjustable and the electronic device is secured against said framework by said fingers.

7. The adjustable holding apparatus as in claim 1, wherein said holder portion includes a framework and a plurality of spring-loaded fingers coupled to said framework, each said finger being configured to move between a normally retracted configuration and an extended configuration, whereby said holder portion is size adjustable and the electronic device is secured against said framework by said plurality of fingers.

8. The adjustable holding apparatus as in claim 7, wherein said framework includes peripheral edges, said plurality of fingers being operably coupled to respective edges of said peripheral edges.

9. The adjustable holding apparatus as in claim 1, wherein said base assembly includes a platform coupled to said lower end of said vertical support member and having a generally planar configuration.

10. The adjustable holding apparatus as in claim 9, wherein said platform has a thin thickness.

11. The adjustable holding apparatus as in claim 10, wherein said platform is pivotally coupled to said lower end of said vertical support member such that said platform is movable between a folded configuration generally parallel to said vertical support member and an unfolded configuration generally perpendicular to said vertical support member.

12. The adjustable holding apparatus as in claim 1, wherein:
said lower portion of said vertical support member defines a plurality of spaced apart holes;
said upper portion of said vertical support member includes a plurality of spaced apart spring-loaded buttons; and
said holes and said buttons are configured to register respectively such that said vertical support member is selectively length adjustable.

13. The adjustable holding apparatus as in claim 1, wherein said base assembly includes a tripod having a plurality of legs movable between retracted and extended configurations.

14. The adjustable holding apparatus as in claim 9, wherein said pivot coupling is a hinge.

15. The adjustable holding apparatus as in claim 1, wherein said pivot coupling is a hinge.
